(19) United States
(12) Patent Application Publication
(10) Pub. No.: US 2005/0073822 A1
(43) Pub. Date: Apr. 7, 2005

(54) Electromagnetic interference shielding assembly

(76) Inventors: Ya-Wen Hsu, KaoHsiung (TW); Shin-Ying Lin, Taipei (TW); Tai-Tung Lien, MiaoLi (TW)

Correspondence Address: BIRCH STEWART KOLASCH & BIRCH, PO BOX 747, FALLS CHURCH, VA, 22040-0747, US

(21) Appl. No.: 10/679,396

(22) Filed: Oct. 7, 2003

(51) Int. Cl. H05K 9/00

(52) U.S. Cl. 361/818

(57) ABSTRACT

An EMI shielding assembly having a surface plate formed as a single unit with one or more wall components is disclosed. The surface plate of the shielding assembly is divided into different zones by the wall component. When the shielding assembly is mounted onto a circuit board, not only the electromagnetic waves generated by the electronic components installed within the area of different zones are prevented by the shielding of the surface plate from leaking outside, but also the aforementioned waves are isolated by the wall components that cross components EMI effect is prevented from happening. Therefore, the goal that not only prevent the electromagnetic wave generated by the electronic components on the circuit board from leaking outside, but also prevent the cross components EMI effects between the different electronic components installed on the same circuit board by a single unit shielding assembly is achieved.

### BACKGROUND OF THE INVENTION

(a). Field of the Invention

The present invention relates to an electromagnetic interference (EMI) shielding assembly, more particularly, to a metallic shielding assembly installed on a printed circuit board (PCB) for preventing cross components EMI effects.

(b). Description of the Prior Arts

With the progress of electronic technology, many kinds of electronic devices have become necessities for human living. From the home appliances, such as refrigerator, television, microwave, cordless phone, etc. to the products of information technology (IT), such as computer, mobile phone, personal digital assistant (PDA), etc., our daily life and environment are surrounded with those electronic devices. However, all the electronic devices, more or less, will generate electromagnetic waves. Thus, in order to prevent the influence or interference incurred by these electromagnetic waves from affecting human body or other electronic devices nearby, various kinds of specified international regulations are made in many classes of electronic devices for reducing the influence of electromagnetic interference (EMI).

General speaking, the most straightforward method to reduce EMI is by wrapping the electromagnetic-wave-generating components with a metal shell (or a plastic casing containing a metallic layer) which is impenetrable by electromagnetic wave. Various kinds of metal shells of prior arts have been disclosed and widely used in public. However, all those prior arts have a common shortcoming, i.e. all those prior arts can only prevent the electromagnetic waves generated by the electronic components inside the metal shell from leaking outside the metal shell, but can not prevent the EMI from leaking between the different electronic components inside the metal shell.

In fact, how to prevent cross components EMI effects is a very important issue. For instance, in an electronic communication device, it is all too common to have both transceivers which are used for processing analogue signals, and logical operators which are used for processing digital signals, etc, on a printed circuit board. Under the way, the analogue signals are prone to be affected by the digital signals and the incurred electromagnetic waves so that noises and signal distortions are generated. At the same time, the mutual interference also likely occurs between the high-frequency logical operators. Traditionally, in the electronic devices having larger printed circuit board, such as desktop computer, notebook computer, etc., the effect of EMI can be reduced by enlarging the interval between high-frequency electronic components (or analogue electronic components). However, for those portable electronic devices having a smaller printed circuit board, such as mobile phone, PDA, computer cards etc., the effect of EMI obviously can not be reduced by providing adequate interval between the electronic components on such a smaller printed circuit board.

Although the prior art can prevent different electronic components deployed on the same printed circuit board from being affected by EMI by wrapping each electronic component respectively with an independent metal shell. Nevertheless, the foregoing method will result in not only higher cost and much more troublesome manufacturing process, owing to the method requires to install one or more metal shells on a printed circuit board, but also the increasingly required area of the printed circuit board which is proportional to the number of metal shells needed for connecting the metal shell to the printed circuit board. Therefore, the aforementioned prior arts cannot provide an efficient solution for the electronic devices with small circuit boards, and further improvements are required.

### SUMMARY OF THE INVENTION

The primary object of the present invention is to provide an EMI shielding assembly having one single shield installed on a circuit board, which can prevent the electromagnetic wave generated by the electronic components of the circuit board from leaking outside, even prevent the EMI from happening between the different electronic components installed on the same circuit board.

Another object of the present invention is to provide an EMI shielding assembly having different zones formed on the assembly by using a means of partition, moreover, the means of partition is able to prevent EMI from happening between the aforementioned zones.

Yet another object of the present invention is to provide an EMI shielding assembly, which is a metal plate having wall components formed on predetermined positions of the metal plate by stamping process. When the metal plate is mounted onto the circuit board, the electromagnetic waves generated by the electronic components located on the opposite side of one of the aforementioned wall components are isolated from each other by the wall components, and the cross components EMI phenomenon is prevented from happening.

In order to achieve the foregoing object, the present invention provides an EMI shielding assembly that can be mounted onto a circuit board. The EMI shielding assembly is made of an electromagnetic wave impenetrable material, which comprises a surface plate, at least one slot for partitioning the surface plate into different zones which have one or more wall components in at least one zone, and at least one side wall. The surface plate is extending along a horizontal plane and covers a predefined area. The wall component is connected to the surface plate and having a predetermined length extending horizontally along the horizontal plane of the surface plate and a predetermined height standing perpendicular to the horizontal plane. The area covered by the surface plate can be divided by the wall component into different zones, e.g. a first zone and a second zone. Because the wall component is also made of an electromagnetic wave impenetrable material, it can prevent the EMI between the two zones from happening. In this regard, the object of using a single EMI shielding assembly not only to prevent the electromagnetic wave generated by the electronic components of a circuit board from leaking outside, but also to prevent the EMI from happening between the different electronic components installed on the same circuit board is achieved.

### BRIEF DESCRIPTION OF THE DRAWINGS

FIG. 1 is a top perspective view showing a preferred embodiment of an EMI shielding assembly according to the present invention.

FIG. 2 is a bottom perspective view showing the EMI shielding assembly of FIG. 1.

FIG. 3 is a assembly drawing showing a preferred embodiment of an EMI shielding assembly mounted on a circuit board with reference to FIG. 1.

FIG. 4 is a exploded view of FIG. 3.

### DETAILED DESCRIPTION OF THE PRESENT INVENTION

The present invention provides a EMI shielding assembly having a surface plane formed with at least one slot for defining the surface plane into different zones, and at least one zone has one or more wall components for isolating the different zones, and at least one side wall formed on at least one side of the surface plane. Furthermore, the surface plane with at least one slot, wall components and side wall are formed as a single unit by a manufacturing way, such as stamping, casting or molding. When the EMI shielding assembly is mounted onto a circuit board, not only the electromagnetic waves generated by the electronic components installed within the area of different zones are prevented by the shielding of the surface plate and side wall from leaking outside, but also the cross components EMI effect between the different zones is diminished by the wall components. Therefore, a single-unit EMI shielding assembly cannot only prevent the electromagnetic wave generated by the electronic components of a circuit board from leaking outside, but also prevent cross components EMI effects without other independent accessories.

The objects, spirits and advantages of the preferred embodiments of the present invention will be readily understood by the accompanying drawings and detailed descriptions.

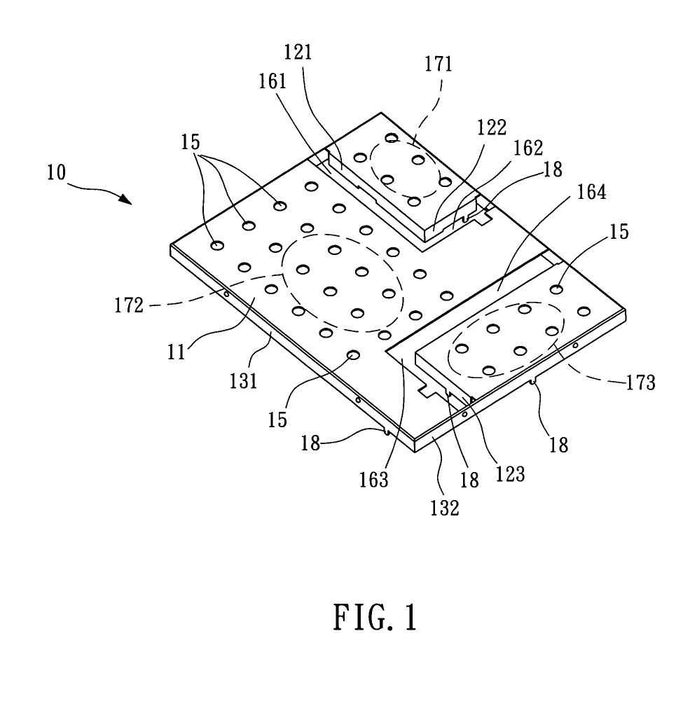

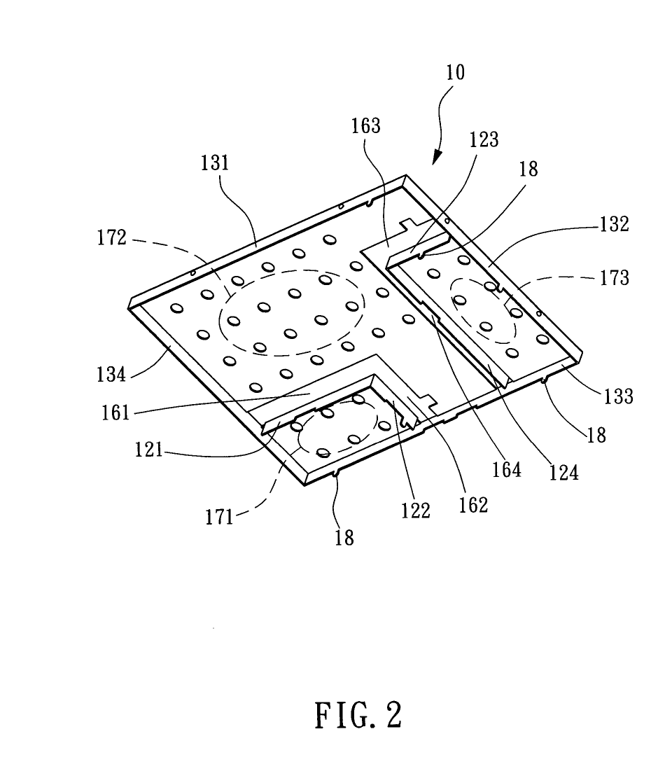

FIG. 1 is a top perspective view showing a preferred embodiment of an EMI shielding assembly 10 according to the present invention. FIG. 2 is a bottom perspective view showing a preferred embodiment of the EMI shielding assembly 10 of FIG. 1. In the embodiment as seen in FIG. 1 and FIG. 2, the EMI shielding assembly 10 is formed (manufactured) by a single plate made of an electromagnetic wave impenetrable material, such as metal plate or other plate-shaped electrical conductive material. Wherein, the metal plate preferably is made of iron, chromium, nickel, copper, aluminum, silver or other metals or alloys, etc. The plate (e.g. metal plate) is processed using stamping process to form an surface plate 11, wall components 121, 122, 123, 124, slots 161, 162, 163, 164, side walls 131, 132, 133, 134 encircling the outer rim of the surface plate 11, and one or more holes 15 formed on the surface plate 11 for ventilation.

The surface plate 11 having predetermined dimensions makes up the EMI shielding assembly 10, which is extending along a horizontal plane and covering a predefined area. Each wall component 121˜124 respectively is extending horizontally along the horizontal plane of the surface plate 11 in a first length and is standing perpendicular to the horizontal plane of the surface plate 11 in a first height. On the other hand, each side wall 131˜134 respectively is extending horizontally along the horizontal plane of the surface plate 11 in a second length and is standing perpendicular to the horizontal plane of the surface plate 11 in a second height. Wherein the heights of the wall components 121˜124 can be the same as those of the side walls 131˜134. In the present embodiment, the wall components 121˜124 are formed by cutting and bending downward a portion of the surface plate 11 with the stamping process. Therefore, each wall component 121˜124 has one edge connected to the surface plate 11, and another edge bended below the surface plate 11 with a predetermined height away from the horizontal plane (the surface plate 11). Moreover, the cutting and bending process will result in the slots 161, 162, 163, 164 respectively extending along the length of each wall component 121˜124, also the width of each slot 161˜164 is roughly equal to the height of each corresponding wall component 121˜124.

As seen in FIG. 1 and FIG. 2, the wall components 121˜124 can be set up in pairs, for instance, one end of the wall component 121 contacts with one end of another wall component 122 which is paired with the wall component 121. On the other hand, another end of the wall component 121 contacts with the corresponding side wall 134. Another end of the wall component 122 contacts with the corresponding side wall 133. Hence, an independent zone (which is called first zone 171 hereinafter) is defined by the area covered by the surface plate 11 using the two paired wall components 121, 122 and the two side walls 133, 134. Wherein, the first zone 171 is isolated from the EMI originated from other area covered by the surface plate 1, such as the second zone 172. Similarly, the third zone 173 formed by the other paired wall components 123, 124 and the two side walls 132, 133 is substantially isolated from the EMI originated from the second zone 172. Therefore, the cross components EMI effect is diminished by isolating the zones 171˜173 from each other. Furthermore, the aforementioned holes 15 can be formed optionally at the first zone 171, the second zone 172 and the third zone 173 for ventilation.

Yet, one or more soldering pins 18 are installed on the predefined positions, such as the free edges, of the wall components 122, 123 and/or the side walls 133, 134 according to the designing requirement for mounting the EMI shielding assembly 10 on the circuit board.

In the present embodiment, the first zone 171 (or the third zone 173) is preferable to be deployed at the corner of the surface plate 11 for enabling at least one side (or two sides) of the first zone 171 contacts with the side walls 133, 134, so that the structure rigidness of the first zone 171 and the structure integrity of the EMI shielding assembly 10 are improved. The first zone 171 shown in FIG. 1 and FIG. 2 is not appropriate to be deployed at the center of the surface plate 1, since the first zone 171 deployed at the center of the surface plate 11 will be detached from the surface plate 11 and cannot be formed with the other parts of the EMI shielding assembly as a single unit.

In another embodiment (not shown), the wall components can be formed without using the stamping process to bend a portion of the surface plate. Comparatively, the wall component can be fabricated independently in advance and then be combined with the surface plate by welding, gluing, clipping, or other equivalent means. Moreover, the other method can be used to produce the EMI shielding assembly, such as casting, so that the first zone (or the third zone) can be located at the center of the surface plate without the need to contact with the side walls, and in consequence there is also no slot existing on the surface plate. However, the method that forms the wall component independently and then combines the wall components with the surface plate will increase the manufacturing cost of the EMI shielding assembly of the present invention. On the other hand, the method using casting will result in the increase of volume and weight of the EMI shielding assembly.

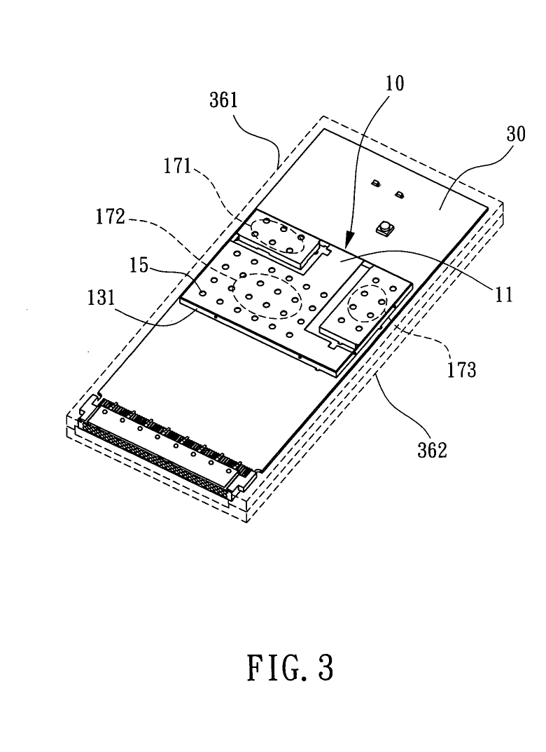

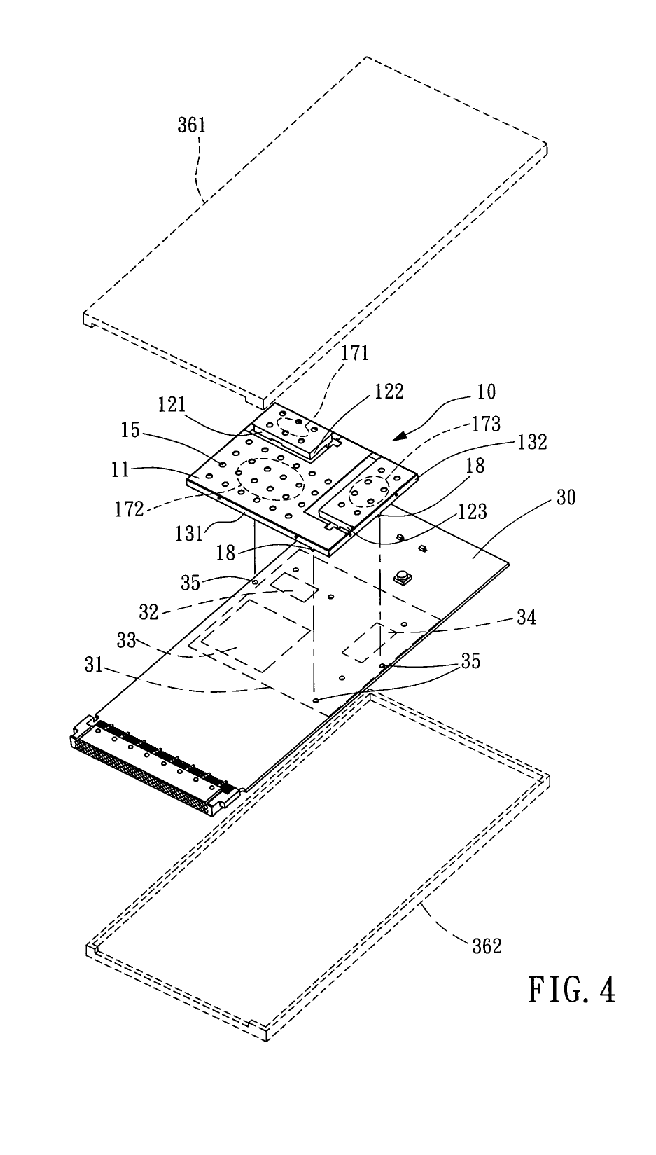

Please refer to FIG. 3 and FIG. 4, wherein FIG. 3 is a assembly drawing showing a preferred embodiment of an EMI shielding assembly 10 configured on a circuit board 30 with reference to FIG. 1, and FIG. 4 is a exploded view of FIG. 3.

As seen in FIG. 3 and FIG. 4, the EMI shielding assembly 10 can be mounted on a circuit board 30. The circuit board 30 can be (but is not limited to be) a printed circuit board of a computer card compatible with the PCMCIA standards. There are electronic components and circuit layouts installed on a predefined area 31 of the circuit board 30, and further in the present embodiment, the electronic components and circuit layouts require adequate partitions (i.e. for preventing cross components EMI effect) to divide the electronic components and circuit layouts into at least a first group of electronic components 32, a second group of electronic components 33 and a third group of electronic components 34.

With mounting the EMI shielding assembly 10 onto the circuit board 30, the surface plate 11 is roughly covering the predefined area 31 of the circuit board 30. The position of the first group of electronic components 32 is roughly within the first zone 171, the second group of electronic components 33 is roughly within the second zone 172, and the third group of electronic components 34 is roughly within the third zone 173. Since the side walls 133˜134 are encircling the outer rim of the surface plate 11, and the wall components 121˜124 create zones 171˜173, the cross components EMI effect will not occur between different groups of electronic components 32˜34 respectively located within corresponding different zones 171˜173, and the electromagnetic waves generated by all the electronic components within the predefined area 31 will not leak outside the EMI shielding assembly. Accordingly, the aforementioned goal can be achieved by using the single EMI shielding assembly 10 which indeed can solve the shortcomings with reference to the prior arts.

As seen in FIG. 4, the EMI shielding assembly 10 of the present invention is mounted onto the circuit board 30 by inserting the soldering pins 18 formed on the EMI shielding assembly 10 into pin holes 35 formed on the circuit board 30. The initial positioning and assembling of the EMI shielding assembly 10 and the circuit board 30 are achieved by inserting the soldering pins 18 into the corresponding pin hole 35, and then affixing them together by a way, such as soldering, surface mount technology (SMT), gluing, riveting (bending and buckling the pins 18), etc. Finally, the EMI shielding assembly 10 and the circuit board 30 is enclosed by the upper casing 361 and lower casing 362, so that a computer card as seen in FIG. 3 is accomplished.

To sum up, the EMI shielding assembly of the present invention uses wall components to form different zones on the surface plate and isolate those zones from each other. The configuration of the wall components between different zones can efficiently prevent EMI from occurring between different zones, moreover, the object of using one single unit EMI shielding assembly to prevent both the electromagnetic wave from leaking outside and the cross components EMI effect between the different electronic components installed on the same circuit board is achieved. In this regard, the shortcomings with reference to the prior arts are believed to overcome.

Those skilled in the art should appreciate that they can readily use the disclosed conception and specific embodiments as a basis for designing or modifying other structures for carrying out the same purpose of the present invention, and that various changes, substitutions and alterations can be made herein without departing from the spirit and scope of the invention as defined by the append claims.

1. An EMI shielding assembly for mounting on a circuit board having various electronic components, comprising:
a surface plate;
at least one slot for defining different zones on said surface plate, at least one zone having one or more wall components for isolating said different zones; and
at least one side wall formed on at least one side of said surface plate for securing on said circuit board;
wherein said surface plate, said slot, and said side wall are formed as a single unit.

2. The EMI shielding assembly of claim 1, wherein said surface plate has one or more holes for ventilation.

3. The EMI shielding assembly of claim 1, wherein said surface plate are substantially parallel to said circuit board.

4. The EMI shielding assembly of claim 1, wherein said wall components are formed with one or more soldering pins.

5. The EMI shielding assembly of claim 1, wherein said side wall is formed with one or more soldering pins.

6. The EMI shielding assembly of claim 1, wherein said surface plate, said slot, and said side wall are formed as a single unit by stamping from sheet metal.

7. The EMI shielding assembly of claim 1, wherein said wall components and said side wall function for isolating said various electronic components.
